(19) United States
(12) Patent Application Publication
(10) Pub. No.: US 2006/0275944 A1
(43) Pub. Date: Dec. 7, 2006

(54) CMOS image sensor and method for fabricating the same

(76) Inventor: Kim Seoung Hyun, Pocheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/446,659

(22) Filed: Jun. 5, 2006

(30) Foreign Application Priority Data
Jun. 3, 2005 (KR) 10-2005-0047636

(51) Int. Cl. H01L 21/00; H01L 27/10

(52) U.S. Cl. 438/70; 257/204

(57) ABSTRACT

A CMOS image sensor and a method of fabricating the same are provided. The CMOS image sensor can incorporate one or more photodiodes formed on a substrate at a regular interval, an interlayer insulating layer formed on the substrate; one or more trenches in the interlayer insulating layer at predetermined locations corresponding to the photodiodes, a color filter layer formed in each of the trenches; and at least one microlens corresponding to a color filter layer formed on the resulting substrate. The sensitivity of the CMOS image sensor is improved by reducing the thickness of the CMOS image sensor by forming the trenches in the interlayer insulating layer and forming the color filters in the trenches.

### RELATED APPLICATION

This application claims the benefit, under 35 U.S.C. §119(e), of Korean Patent Application No. 10-2005-0047636 filed Jun. 3, 2005, which is incorporated herein by reference in its entirety.

### FIELD OF THE INVENTION

The present invention relates to a CMOS image sensor and a method for fabricating the same, and more particularly, to a CMOS image sensor for improving sensitivity by reducing the overall thickness of the CMOS image sensor and a method of fabricating the same.

### BACKGROUND OF THE INVENTION

In general, an image sensor is a semiconductor device that transforms an optical image to an electric signal. An image sensor can be classified as a charge coupled device (CCD) or complementary metal oxide silicon (CMOS) image sensor.

The CCD has shortcomings such as a complicated driving method and high power consumption. Also, the fabricating method for the CCD is complicated because a multi-level photo process is required.

Therefore, the CMOS image sensor has received attention as a next-generation image sensor to overcome the shortcomings of the CCD.

The CMOS image sensor reconstructs an image by sequentially detecting electric signals of each of its unit pixels based on a switching mode. Each unit pixel incorporates a photodiode and a MOS transistor to select that unit pixel.

FIG. 1 is a cross-sectional view of a CMOS image sensor according to the related art.

As shown in FIG. 1, in order to form the CMOS image sensor according to the related art, photodiodes 20 are formed on a substrate 10 at a regular interval and light-shielding layers 30 are formed between photodiodes 20.

Then, an interlayer insulating layer 40 is formed on the light-shielding layer formed substrate 10.

Then, color filter layers 50R, 50G, and 50B are formed on the interlayer insulating layer 40, and a planarizing layer 60 is formed on the color filter layers 50R, 50G, and 50B. The planarizing layer 60 is currently formed to be about 2000 A because of the step difference of the color filter layers 50R, 50G, and 50B.

Then, microlenses 70 are formed on the planarizing layer 60.

However, the CMOS image sensor of the related art has the problem that a focal length A, which is the path of light incident through the micro lens 70 to reach a photodiode 20, becomes longer as the CMOS image sensor becomes thicker. This thickening of the CMOS image sensor is partially due to the tendency of forming multiple metal lines.

Since the sensitivity of the image sensor is degraded as the focal length A becomes longer, the thickness of the CMOS image sensor becomes a factor that degrades the performance of the CMOS sensor.

Because the planarizing layer 60 is formed to be relatively high, for example, about 2000 Å, in order to correct for the step difference of the color filter layers 50, the overall thickness of the CMOS image sensor of the related art is increased.

### SUMMARY OF THE INVENTION

Accordingly, the present invention is directed to a CMOS image sensor and method for fabricating the same that can address one or more problems of the related art.

An object of the present invention is to provide a CMOS image sensor and a method for fabricating the same for improving sensitivity by reducing a thickness of the CMOS image sensor.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a CMOS (complementary metal oxide silicon) image sensor including: at least one photodiode formed on a substrate at a regular interval; an interlayer insulating layer formed on the substrate; one or more trenches in the interlayer insulating layer at predetermined locations corresponding to the photodiodes; a color filter layer formed in each of the trenches; and at least one microlens formed on the resulting substrate corresponding to a color filter layer.

In another aspect of the present invention, there is provided a method of fabricating a CMOS image sensor including: forming at least one photodiode on a substrate at a regular interval; forming an interlayer insulating layer on the substrate having the photodiodes; forming at least one trench in the interlayer insulating layer corresponding to the photodiodes; forming a color filter layer in each of the trenches; and forming at least one microlens on the resulting substrate corresponding to the color filter layer.

According to the present invention, the sensitivity of the CMOS image sensor can be improved by reducing the thickness of the CMOS image sensor. In an embodiment, this is accomplished by reducing a region occupied by the interlayer insulating layer and the color filter. In a specific embodiment, this region can be reduced by forming trenches in the interlayer insulating layer of the CMOS transistor and forming the color filters in the trenches. Therefore, the color reproducibility can be enhanced and the image quality can be improved.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view of a CMOS image sensor according to the related art;

FIG. 2 is a cross-sectional view of a CMOS image sensor according to a first embodiment of the present invention;

FIGS. 3a through 3d are cross-sectional views for describing a method of fabricating a CMOS image sensor according to an embodiment of the present invention; and

FIG. 4 is a cross-sectional view of a CMOS image sensor according a second embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a CMOS image sensor and a method for fabricating the same according to the present invention will be described with reference to accompanying drawings.

### First Embodiment

FIG. 2 is a cross-sectional view of a CMOS image sensor according to a first embodiment of the present invention.

Referring to FIG. 2, the CMOS image sensor according to a first embodiment can incorporate photodiodes 120, light-shielding layers 130, an interlayer insulating layer 140 having a trench, color filter layers 150R, 150G, and 150B, and microlenses 170. In a further embodiment, the CMOS image sensor can incorporate passivation layer 142.

The photodiodes 120 can be formed on the surface of the substrate 100 at a regular interval and are capable of generating an electric charge according to the quantity of incident light.

In an embodiment, the light-shielding layers 130 can be made of opaque material, such as, for example, an opaque organic material or an opaque metal. In one embodiment, the light-shielding layer 130 can be a Cr layer. Referring again to FIG. 2, the light-shielding layer 130 is formed on the substrate 110 between the photodiodes 120 to prevent the light from being incident to a photodiode region peripheral to the intended photodiode.

After forming the light-shielding layer 130, an interlayer insulating layer 140 can be formed on the substrate 110 and can incorporate one or more trenches at locations corresponding to the photodiodes 120. In a preferred embodiment, the interlayer insulating layer 140 is an insulating layer having a low dielectric constant. The interlayer insulating layer 140 can be made of any type of insulating materials. In a specific embodiment, an oxide layer can be used for the interlayer insulating layer 140.

According to embodiments of the subject invention, the thickness of a region occupied by the interlayer insulating layer 140 can be reduced by forming the trenches to a predetermined top metal line (not shown) in the interlayer insulating layer 140.

In one embodiment where the predetermined top metal line is not included in the region of the photodiode 140, the depth of the trench in the interlayer insulating layer 120 can be, for example, in a range from 3000 Å to 7000 Å. Accordingly, the thickness of the region occupied by the interlayer insulating layer 140 and the color filters 150R, 150G, and 150B can be reduced by 3000 Å to 7000 Å.

In another embodiment where the predetermined top metal line is included in the region of the photodiode 120, the depth of the trench in the interlayer insulating layer 140 can be, for example, in a range from 2000 Å to 3000 Å. Accordingly, the region occupied by the interlayer insulating layer 140 and the color filters 150R, 150G, and 150B can be reduced by 2000 Å to 3000 Å.

The color filter layers 150R, 150G, and 150B can be formed in the trenches in the interlayer insulating layer 140. The color filter layers 150R, 150G, and 150B can be a red, a sreen and a blue color filter layer that can pass a predetermined wavelength of light.

In a further embodiment, the CMOS image sensor can incorporate a passivation layer 142 formed on the interlayer insulating layer 140. If the CMOS image sensor further includes the passivation layer 142, the color filter layers 150R, 150G, and 150B can be formed on the passivation layer 142 in the trenches. In a specific embodiment, the passivation layer 142 can be made of SiN.

The passivation layer 142 protects elements such as the color filter layers 150R, 150G, and 150B, and can prevent humidity from penetrating the image sensor.

The microlenses 170 can be formed on the color filter layers 150R, 150G, and 150B. The microlenses 170 can be made to have a concave shape with a constant curvature. The microlenses 170 concentrate the light to the photodiode region 120 by passing through the corresponding color filter layers 150R, 150G, and 150B.

Embodiments of the subject invention do not require forming the planarizing layer 60 of the related art because color filter layers 150R, 150G, and 150B can be formed in the trenches of the interlayer insulating layer 140.

Therefore, a focal length B, which is a path of light incident through the micro lens 170 to reach the photodiode 120, can be shortened in a range, for example, from 3000 Å to 7000 Å, by removing the region formerly occupied by the planarizing layer 60 and reducing the region formerly occupied by color filter layers 50R, 50G, and 50B. Accordingly, the performance of the CMOS image sensor can be improved through improving the sensitivity of the light incident to the photodiode 120 by reducing the focal length B.

Hereinafter, a method of fabricating a CMOS image sensor according to a first embodiment of the present invention will be described.

The method of fabricating a CMOS image sensor according to a first embodiment can incorporate forming a photodiode, forming an interlayer insulating layer having a trench, forming color filter layers, and forming microlenses.

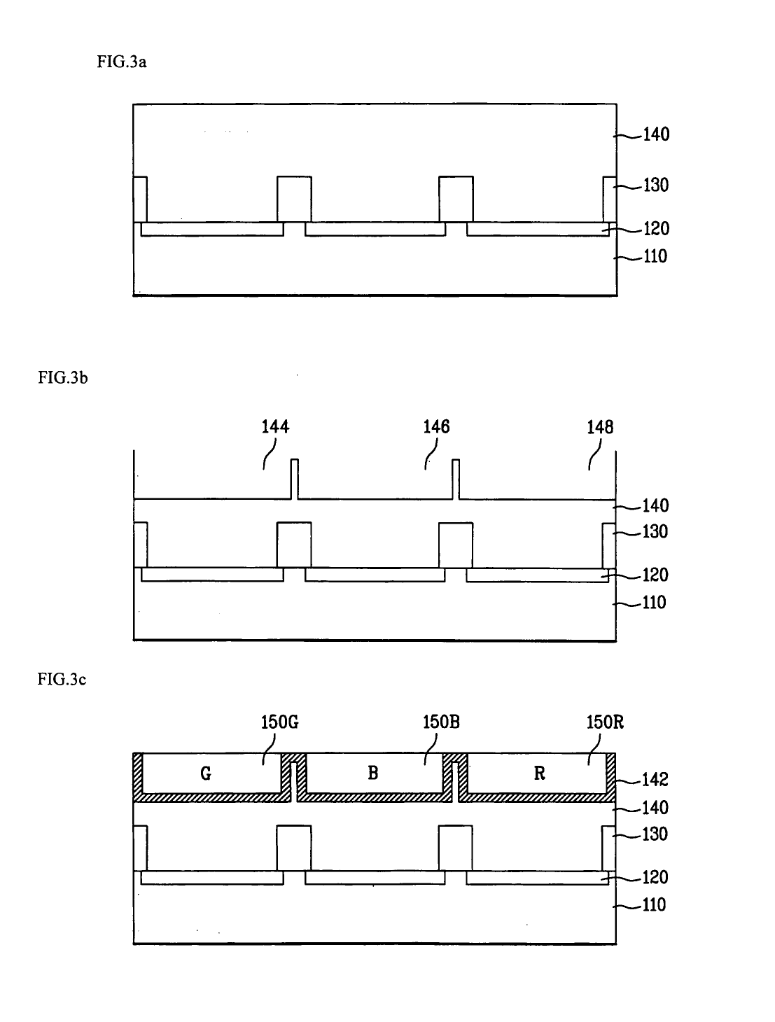

FIGS. 3a through 3d are cross-sectional views for describing a method of fabricating a CMOS image sensor according to an embodiment of the present invention.

As shown in FIG. 3a, one or more photodiodes 120 can be formed on the surface of a substrate 110 at regular intervals.

Then, an opaque material, for example, a Cr layer, can be deposited on the entire surface of the substrate 110 having the photodiodes 120. In a specific embodiment, the light-shielding layers 130 can be formed by selectively patterning the Cr layer to leave the Cr layer between the photodiodes 120 on the substrate 110. The selective patterning can be accomplished by performing photolithography and etching processes.

Then, an interlayer insulating layer 140 can be formed on the substrate 110 having the light-shielding layers 130. In an embodiment, the interlayer insulating layer 140 can be formed as multiple layers.

In one embodiment, the interlayer insulating layer 140 can be formed by depositing an insulating material having a low dielectric constant through a chemical vapor deposition (CVD). In a specific embodiment, the insulating material can be an oxidation layer.

As shown in FIG. 3b, at least one of trenches 144, 146 and 148 can be formed by selectively etching the interlayer insulating layer 140 to be correspondent to one of the photodiodes 120.

In an embodiment, a dry etching process using RIE (Reactive Ion Etching) can be used to etching the interlayer insulating layer 140.

According to embodiments of the subject invention, the thickness of a region occupied by the interlayer insulating layer 140 can be reduced by forming the trench to a predetermined top metal line (not shown) in the interlayer insulating layer 140.

In one embodiment where the predetermined top metal line is not included in the region of the photodiode 120, the trench can be formed by etching the interlayer insulating layer 140 in a range from 3000 Å to 7000 Å.

In another embodiment where the predetermined top metal line is included in the region of the photodiode 120, the trench can be formed by etching the interlayer insulating layer 140 in a range from 2000 Å to 3000 Å.

As shown in FIG. 3c, a passivation layer 142 can be formed on the entire surface of the substrate 110 having the trenches 144, 146 and 148. In a specific embodiment, the passivation layer can be made of a nitride layer, for example, SiN.

In an embodiment, the color filter layers 150R, 150G, and 150B, which filter the light according to corresponding wavelength, can be formed by applying a dyeable photoresist to the resulting substrate and trenches 144, 146, and 148, and then patterning the dyeable photoresist through an exposing and developing process.

In an embodiment, a planarizing process can be performed to remove a step difference among the color filter layers 150R, 150G, and 150B that are separated at regular intervals. In a specific embodiment, an etch back process or a chemical mechanical polishing process can be used for the planarizing process of the color filter layers 150R, 150G, and 150B.

As shown in FIG. 3d, microlenses 170 can be formed on the color filter layers 150R, 150G, and 150B in a convex shape having a predetermined curvature. The microlenses 170 can condense the light to the photodiode region 120 by passing through the color filter layers 150R, 150G, and 150B. In an embodiment, the microlenses 170 can be correspondently formed on the color filter layers 150R, 150G, and 150B by depositing dielectric material on the color filter layers 150R, 150G, and 150B, and then selectively removing the deposited dielectric material through photolithography and etching processes.

According to embodiments of the subject invention, a focal length B, which is a path of light incident through the micro lens 170 to reach the photodiode 120, can be shortened. Therefore, the sensitivity of the image sensor can be improved, and the performance of the CMOS image sensor is enhanced thereby.

According to embodiments of the subject invention, the performance of the CMOS image sensor can be improved by improving the sensitivity of the light incident to the photodiode by reducing the thickness of the CMOS image sensor through removing the need for a planarizing layer 60.

Differently from the conventional technology, the thickness of the CMOS image sensor can be reduced by reducing the region occupied by the color filter layers 150R, 150G and 150B and the interlayer insulating layer 140 through the forming of the trenches in the interlayer insulating layer 140 and the forming of the color filter layers 150R, 150G and 150B in the trenches of interlayer insulating layer 140. Since the sensitivity of the CMOS image sensor is improved by reducing the thickness of the CMOS image sensor, the quality of the output image can be improved by enhancing the color reproducibility.

### Second Embodiment

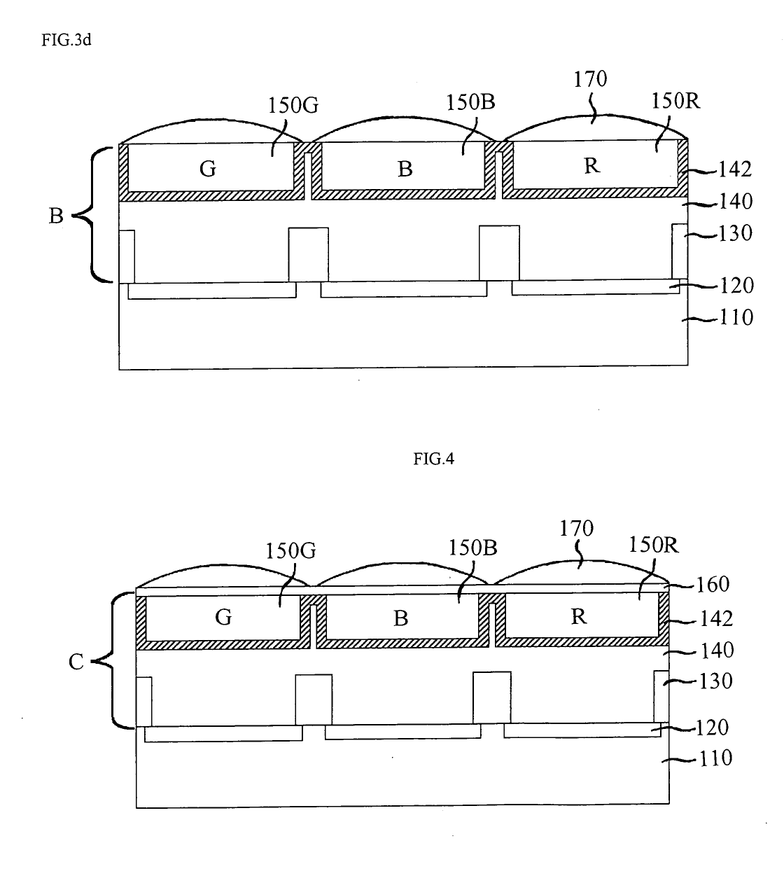

FIG. 4 is a cross-sectional view of a CMOS image sensor according a second embodiment of the present invention.

Referring to FIG. 4, the CMOS image sensor according to the second embodiment can incorporate photodiodes 120 formed on a substrate 110, light-shielding layers 130, an interlayer insulating layer 140 having trenches, a passivation layer 142, color filter layers 150R, 150G, and 150B, a planarizing layer 160 and microlenses 170.

The CMOS image sensor according to the second embodiment can be a further embodiment of the first embodiment discussed above. In particular, the second embodiment can further incorporate a thin planarizing layer 160 on the color filter layers 150R, 150G, and 150B..

A method of fabricating the CMOS image sensor according to the second embodiment can employ the method of fabricating the CMOS image sensor discussed above.

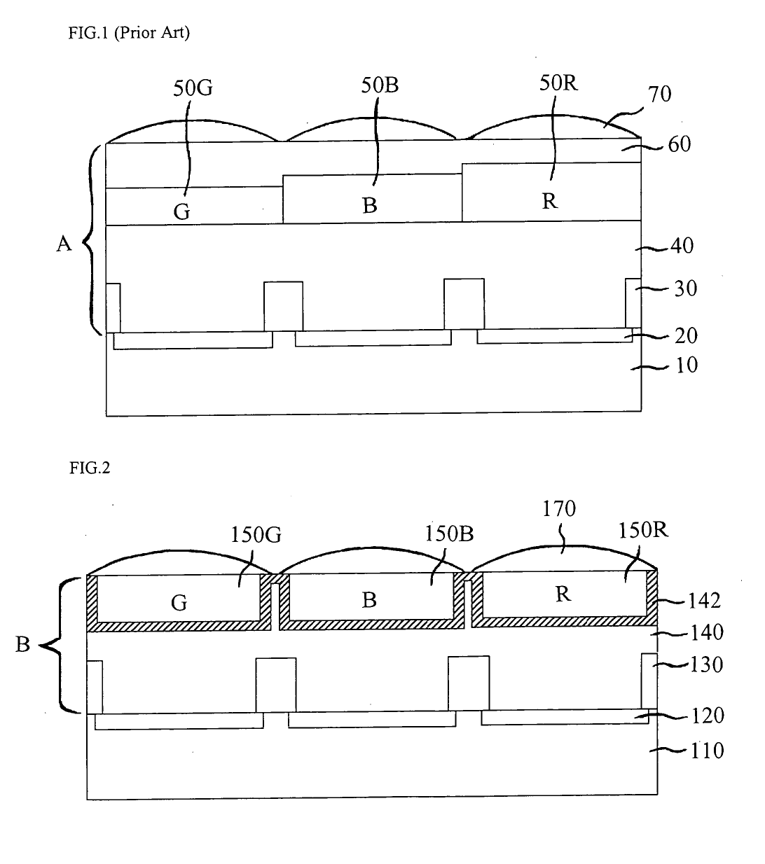

As shown in FIG. 4, in one embodiment, the planarizing layer 160 can be formed on the substrate 110 by performing a spin coating process with a photo resist. The thickness of the planarizing layer 160 is thinner than the conventional planarizing layer 60 shown in FIG. 1 because the step difference between the color filter layers 150R, 150G, and 150B is reduced.

In the CMOS image sensor according to the second embodiment, the color filter layers 150R, 150G and 150B can be formed without the step difference seen in FIG. 1 by forming the trench in the interlayer insulating layer 140.

Therefore, the thickness of the planarizing layer 160 in the second embodiment can be reduced compared to that of the conventional planarizing layer 60.

In particular, the thickness of the planarizing layer 60 must be, for example, about 2000 Å, because the step difference among the color filter layers 50R, 50G, and 50B is very large.

In contrast, the thickness of the planarizing layer 160 can be reduced to be less than about 100 Å by forming the color filter layers 150R, 150G, and 150B in the trenches of the interlayer insulating layer 140 with a very short step difference.

Accordingly, a focal length C, which is a path of the light incident through the microlens 170 to the photodiode 120, can be shortened by reducing the thickness of the CMOS image sensor. Therefore, the performance of the CMOS image sensor can be improved by improving the sensitivity of the light incident to the photodiode.

According to embodiments of the subject invention incorporating planarizing layer 160, the sensitivity of the CMOS image sensor can be improved by reducing the thickness of the CMOS image sensor by reducing the region occupied the interlayer insulating layer 140 through forming the trenches in the interlayer insulating layer 140. Therefore, the color reproducibility can be improved, and the quality of the output image can be improved.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CMOS (complementary metal oxide silicon) image sensor, comprising:
one or more photodiodes formed on a substrate at a regular interval;
an interlayer insulating layer formed on the substrate;
one or more trenches formed in the interlayer insulating layer at predetermined locations corresponding to the one or more photodiodes;
a color filter layer formed in each of the one or more trenches; and
one or more microlenses formed on the resulting substrate.

2. The CMOS image sensor according to claim 1, further comprising a passivation layer formed in the one or more trenches.

3. The CMOS image sensor according to claim 2, wherein the color filter layer is formed on the passivation layer formed in the one or more trenches.

4. The CMOS image sensor according to claim 2, wherein the passivation layer is formed of SiN.

5. The CMOS image sensor according to claim 1, further comprising a planarizing layer formed on the color filter layer and below the one or more microlenses.

6. The CMOS image sensor according to claim 5, wherein the thickness of the planarizing layer is less than about 100 Å.

7. The CMOS image sensor according to claim 1, further comprising at least one light-shielding layer formed between adjacent photodiodes.

8. The CMOS image sensor according to claim 7, wherein the at least one light-shielding layer is made of an opaque dielectric material or an opaque metal material.

9. The CMOS image sensor according to claim 1, wherein the depth of the one or more trenches in the interlayer insulating layer is in a range from 3000 Å to 7000 Å if a top metal line is not above the one or more photodiodes.

10. The CMOS image sensor according to claim 1, wherein the depth of the one or more trenches in the interlayer insulating layer is in a range from 2000 Å to 3000 Å if a top metal line is above the one or more photodiodes.

11. A method of fabricating a CMOS image sensor, comprising:
forming one or more photodiodes on a substrate at a regular interval;
forming an interlayer insulating layer on the substrate having the one or more photodiodes;
forming one or more trenches in the interlayer insulating layer corresponding to the one or more photodiodes;
forming a color filter layer in each of the one or more trenches; and
forming one or more microlenses on the resulting substrate.

12. The method according to claim 11, further comprising forming a passivation layer in the one or more trenches.

13. The method according to claim 12, wherein the color filter layer is formed on the passivation layer formed in the one or more trenches.

14. The method according to claim 12, wherein the passivation layer is formed of SiN.

15. The method according to claim 11, further comprising planarizing the color filter layer.

16. The method according to claim 11, further comprising forming a planarizing layer above the color filter layer and below the one or more microlenses.

17. The method according to claim 11, wherein forming the one or more trenches comprises etching the interlayer insulating layer to form the depth of the trenches in a range from 3000 Å to 7000 Å if a top metal line is not included above the one or more photodiodes.

18. The method according to claim 11, wherein forming of the one or more trenches comprises etching the interlayer insulating layer to form the depth of the trenches in a range from 2000 Å to 3000 Å if a top metal line is included above the one or more photodiodes.

19. The method according to claim 11, wherein forming the one or more trenches comprises dry etching the interlayer insulating layer using RIE.

20. The method according to claim 11, further comprising forming at least one light-shielding layer on the substrate between adjacent photodiodes.
